(19) United States
(12) Patent Application Publication
(10) Pub. No.: US 2009/0160047 A1
(43) Pub. Date: Jun. 25, 2009

(54) DOWNHOLE TOOL

(75) Inventors: AKIRA OTSUKA, TOKYO (JP); SHOHACHI MIYAMAE, TOKYO (JP); JIRO TAKEDA, TOKYO (JP)

Correspondence Address: SCHLUMBERGER K.K., 2-2-1 FUCHINOBE, SAGAMIHARA-SHI, KANAGAWA-KEN, 229-0006, JP

(73) Assignee: SCHLUMBERGER TECHNOLOGY CORPORATION, Sugar Land, TX (US)

(21) Appl. No.: 11/963,766

(22) Filed: Dec. 21, 2007

(51) Int. Cl. H01L 23/49; H01L 21/50

(52) U.S. Cl. 257/704; 438/118; 257/E23.024; 257/E21.499

(57) ABSTRACT

A downhole tool having at least one semiconductor device, including: a die; a bonding pad which is attached to the surface of the die; a bonding wire which is attached to the bonding pad; a bonding point which is formed on the bonding pad for connecting the bonding wire to the bonding pad; an encapsulating resin encapsulating the die and being provided with a cavity such that a connecting portion of the bonding point and the bonding pad is exposed out of the resin in the cavity; and a lid on the encapsulating resin to cover the cavity.

### BACKGROUND

1. Technical Field

The present invention relates to a tool having a semiconductor device for high temperature applications, such as in downhole tools, and a method of manufacturing such a semiconductor device.

2. Related Art

Typically, semiconductor devices are packaged using plastic encapsulated packaging. However, in certain circumstances the plastic packaging may pose problems in certain operating conditions. Specifically, plastic encapsulated semiconductor devices are found to have serious difficulties at high temperatures above about 150° C.

U.S. Pat. No. 6,429,028 discloses a process to remove a semiconductor die from a plastic package, and then to reassemble the die in a hermetic package. After removal, the die is reattached and the die wires are rebonded into either a hermetic package or a different type of package. Thus, the die is repackaged in a different type of package. However, there are difficulties in reattaching the die and rebonding all the die wires. For example, when the die wires of the original plastic package are removed, the replacement die wires need to be attached to the bonding pads of the removed die. However, when the die wires are removed the surfaces of the bonding pads are made uneven so that extra processes are required to smooth the surfaces of the bonding pads.

### SUMMARY OF THE INVENTION

The present invention addresses the above and other problems in the currently available techniques for extending high temperature operational limits of commercially available off-the-shelf semiconductor devices. The present invention discloses a relatively simple technique for addressing high temperature associated problems with plastic encapsulated semiconductor devices that are commercially available.

According to the present invention, a downhole tool comprises a tool body; and an electronic module housed in the tool body, which includes a circuit board having a semiconductor device, the semiconductor device including: a die; a bonding pad which is attached to the surface of the die; a bonding wire which is attached to the bonding pad; a bonding point which is formed on the bonding pad for connecting the bonding wire to the bonding pad; an encapsulating resin encapsulating the die and being provided with a cavity such that a connecting portion of the bonding point and the bonding pad is not covered by the resin in the cavity; and a lid formed on the encapsulating resin to cover the cavity.

In one aspect, the present invention discloses a semiconductor device and a method of manufacturing a semiconductor device, including: providing a semiconductor device including a die; a bonding pad which is attached to the surface of the die; a bonding wire which is attached to the bonding pad; a bonding point which is formed on the bonding pad for connecting the bonding wire to the bonding pad; and an encapsulating resin that encapsulates the die to embed the die therein; forming a cavity at a top side of the resin encapsulated semiconductor device by removing a part of the encapsulating resin such that a connecting portion of the bonding point and the bonding pad is exposed out of the resin in the cavity; and attaching a lid on the encapsulating resin to cover the cavity.

### BRIEF DESCRIPTION OF THE DRAWINGS

The above and other objects, advantages and features of the present invention will be more apparent from the following description taken in conjunction with the accompanying drawings, in which:

FIG. 1 shows a sectional view of an example of the original semiconductor package;

FIG. 2 shows a flow chart of a method of manufacturing a semiconductor device according to the present invention;

FIG. 3 shows a sectional view of the semiconductor device of one embodiment disclosed herein;

FIG. 4 shows a sectional view of the semiconductor device of one embodiment disclosed herein;

FIG. 5 shows a plan view of the semiconductor device as shown in FIG. 3;

FIG. 6 is a schematic representation in cross-section of an exemplary operating environment of the present invention;

FIG. 7 is a schematic representation of one embodiment of a system for downhole analysis of formation fluids according to the present invention; and

FIG. 8 shows schematically one embodiment of a tool string according to the present invention with a fluid analysis module for downhole analysis of formation fluids.

### DETAILED DESCRIPTION

The invention will now be described herein with reference to illustrative embodiments. Those skilled in the art will recognize that many alternative embodiments can be accomplished using the teachings of the present invention and that the invention is not limited to the embodiments illustrated herein for explanatory purposed.

It is to be noted that, in the explanation of the drawings, the same components will be given the same reference numerals, omitting repeated explanation.

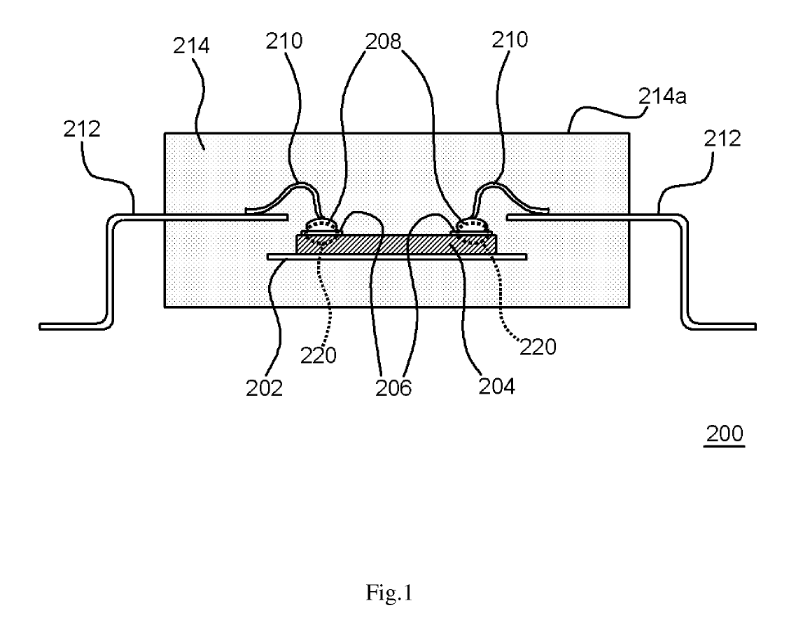

FIG. 1 shows a sectional view of an example of a semiconductor device packaged with plastic encapsulant materials (PEM). The semiconductor device 200 may be a commercial off-the-shelf semiconductor device.

The semiconductor device 200 may include a die pad 202, a die 204, a plurality of bonding pads 206, a plurality of bonding points 208, a plurality of bonding wires 210, a plurality of leads 212, and an encapsulating resin 214. Each bonding pad 206 is attached to the upper surface of the die 204. Each of the bonding pads 206 and the leads 212 are connected via each of the bonding wires 210 and the bonding points 208. The encapsulating resin 214 encapsulates and embeds the die pad 202, the die 204, the bonding pads 206, the bonding points 208, the bonding wires 210 and a part of each of the leads 212. The encapsulating resin 214 may be composed of a plastic including epoxy resin and a chemical material such as bromine or the like that functions as a flame retardant. The bonding points 208 may be formed of gold. The bonding pads 206 may be formed of aluminum.

It is found that the main reasons for the difficulties in the semiconductor devices with PEM at high temperatures are mechanical stresses due to the existence of the plastic composing the encapsulating resin 214 around a connecting portion 220, shown as the dotted circles, of each of the die pads 206 and the bonding points 208, and acceleration of inter-metallic reaction due to the chemical materials contained in the plastic composing the encapsulating resin 214 as flame retardant. The electrical contact between the bonding pad 206 and the bonding point 208 can be lost easily by the mechanical stresses after formation of voids above a certain level due to the chemical reaction that occurs at the interface of the aluminum bonding pad 206 and the gold bonding point 208.

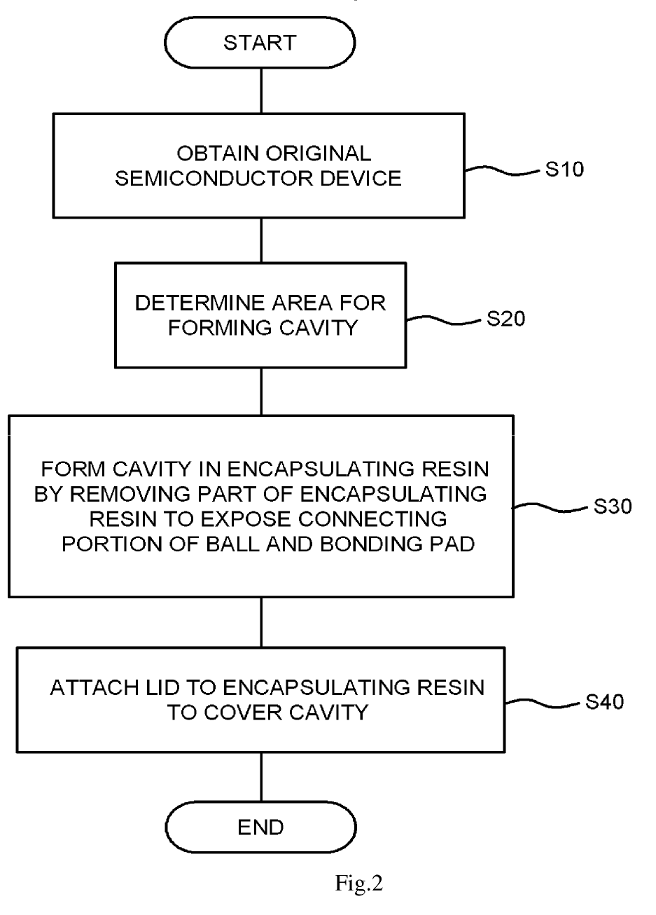

Thus, the present inventors have developed a new semiconductor device to solve the above problems with the original semiconductor devices. FIG. 2 shows a flow chart of a method of manufacturing a semiconductor device according to one embodiment of the present invention.

First, an original commercially available off-the-shelf semiconductor device is obtained (S10). In this embodiment, the original commercial off-the-shelf semiconductor device may be the semiconductor device 200 shown in FIG. 1.

Then, the structure of the original semiconductor device 200 is examined to determine the area for forming a cavity in the encapsulating resin 214 (S20). It is necessary to remove the plastic around the connecting portions 220 of the bonding pads 206 and the bonding points 208 (see FIG. 1), while retaining certain side areas of the encapsulating resin 214 to form side walls of the package for the newly packaged semiconductor device. X-ray transmission images may be used to examine the structure of the original semiconductor device 200 such as the size of the die 204, the position of the bonding pads 206, and the like. Then, the area for forming the cavity is determined based on the structure. In this step, the depth for forming the cavity in the encapsulating resin 214 may also be determined based on the structure.

Subsequently, a cavity is formed in the encapsulating resin 214 from the top side 214a of the semiconductor device 200 by removing a part of the encapsulating resin 214 such that the connecting portions 220 of the bonding points 208 and the bonding pads 206 are exposed (see also FIG. 1) (S30).

After that, a lid is attached to the encapsulating resin 214 to cover the cavity (S40). By retaining enough material for the side walls of the encapsulating resin 214 in step S30, the lid can be tightly fixed to the encapsulating resin 214 even at high temperatures. By these steps, the semiconductor device of the present embodiment is obtained.

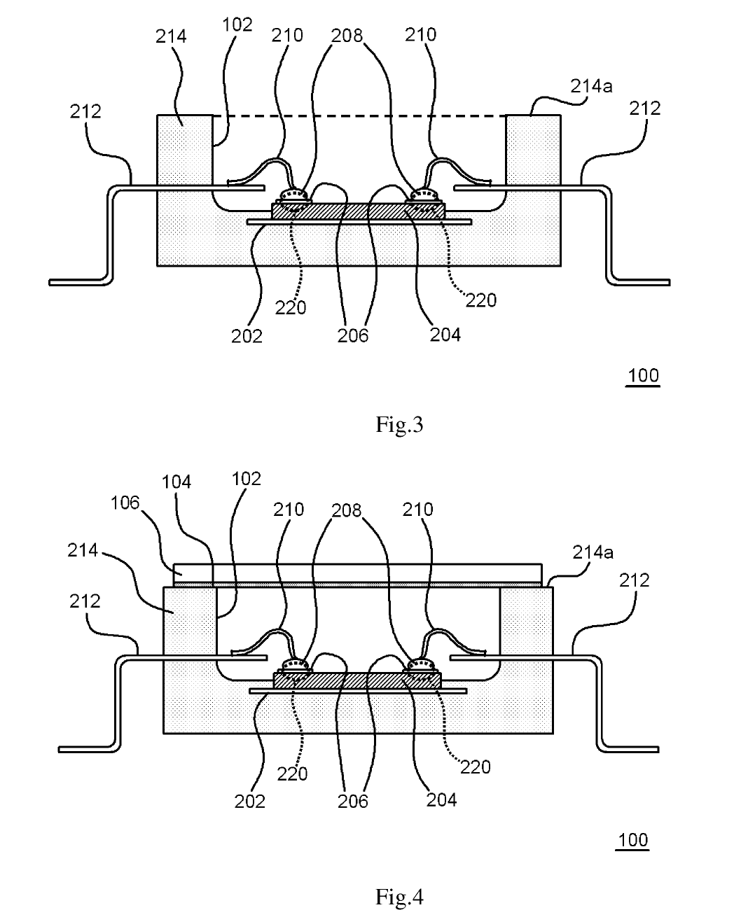

The process will be described in more detail with reference to FIGS. 3 to 5. FIGS. 3 and 4 are sectional views of the semiconductor device of the present embodiment.

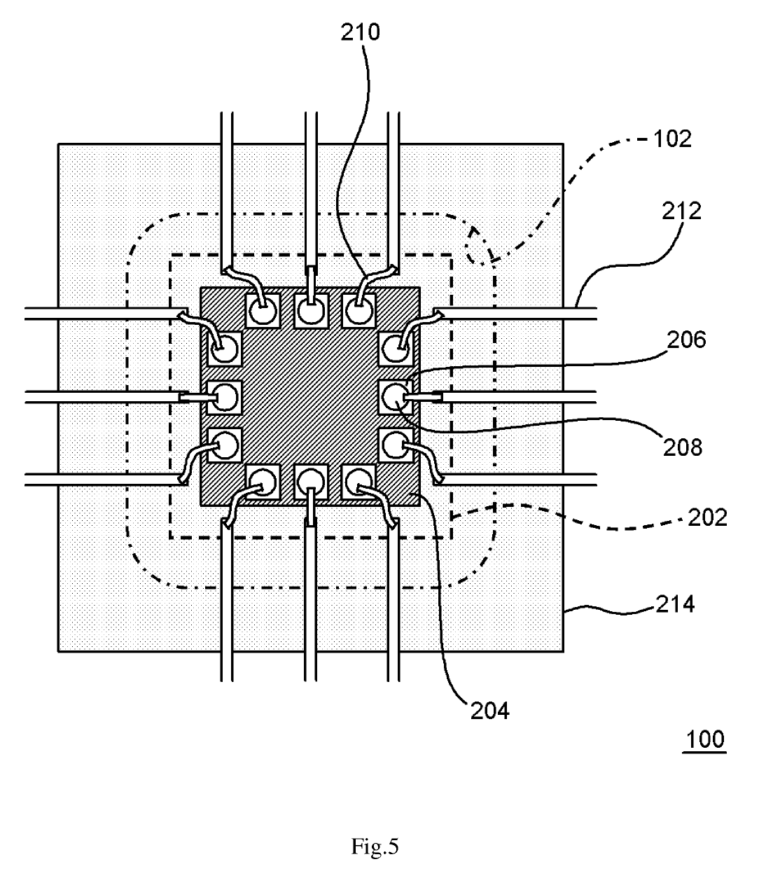

As shown in FIG. 3, a part of the encapsulating resin 214 is removed to form a cavity 102 in the encapsulating resin 214 from the top side 214a of the semiconductor device 200. FIG. 5 is a plan view showing the semiconductor device 100 of the present embodiment as shown in FIG. 3.

The encapsulating resin 214 is removed from the top side 214a by the partial decapsulation method. The partial decapsulation method of the present embodiment is similar to a part of the methods as disclosed in U.S. Pat. No. 6,429,028. Although the die is completely taken out from the original package in U.S. Pat. No. 6,429,028, according to the present embodiment, the die 204 of the original semiconductor device 200 remains in the encapsulating resin 214 as it is. The encapsulating resin 214 is subjected to a localized etch using an etching solution capable of selectively removing the encapsulating resin 214. By the localized etch, a part of the encapsulating resin 214 is removed to form the cavity 102. At this time, the rest of the encapsulating resin 214 forming the side wall and the bottom is not removed. A glass dropper or pipette may be used to produce a directed jet-stream at the targeted area. The targeted area is determined based on the structure of the original semiconductor device 200, as is described in step S20 in FIG. 2. The etching is performed until the surface of the die 204 and the connecting portions 220 of the bonding points 208 and the bonding pads 206 are exposed. In this embodiment, the die pad 202 may be retained in the encapsulating resin 214. With this structure, the die 204 can be fixed by the die pad 202 and the encapsulating resin 214.

The etching solution may be a heated, for example 90° C., jet-stream of either 90% red fuming acid or 90% yellow fuming nitric acid. 20% sulfuric acid may be added to the nitric acid for some types of the plastic composing the encapsulating resin 214. The mix proportion of the etching solution may be properly determined by the types of the plastic and the thickness of the encapsulating resin 214.

To reduce etch time, a topside grinding/milling operation may first be performed to thin down the encapsulating resin 214 immediately above the die area prior to the localized etch.

After the localized etch is completed, the inside of the cavity 102 is rinsed with, for example, acetone. Then, in order to remove the residue of the encapsulating resin 214, the inside of the cavity 102 may be further rinsed with N-methyl-2-pyrrolidinone. Subsequently, the semiconductor device 100 may be rinsed with acetone again.

In addition, for example, when the encapsulating resin 214 is etched by the heated (90° C.) jet-stream of either 90% red fuming acid or 90% yellow fuming nitric acid, a cold, for example, 25° C., jet-stream rinse of the same acid may be performed after the localized etch and before the rinse with the acetone.

Then, the semiconductor device 100 is dried. Subsequently, a lid 106 is attached on the top surface 204a of the encapsulating resin 214, with an adhesive 104 for sealing, to cover the cavity 102, as shown in FIG. 4. The lid 106 may be formed of a ceramic member, a metal member, a plastic member, a glass member, or the like. The adhesive 104 may be composed of a thermosetting resin, such as an epoxy glue. By using the thermosetting resin, such as the epoxy glue, for the adhesive 104, the lid 106 can be fixed to the encapsulating resin 214 even at high temperatures, for example, at 210° C. for 100 hours. Dry inert gas may be filled in the cavity 102 before sealing it with the lid 106 and the adhesive 104.

According to the present embodiment, the bottom of the encapsulating resin 214 of the semiconductor device 100 is the same as that of the original semiconductor device 200. Further, the die pad 202, the die 204, the bonding pads 206, the bonding points 208, the bonding wires 210, and the leads 212 of the semiconductor device 100 do not change from those of the original semiconductor device 200.

However, as the cavity 102 is formed, and the encapsulating resin 214 does not exist around the connecting portions 220 of the bonding pads 206 and the bonding points 208 in the semiconductor device 100 of this embodiment, the present structure disclosed herein can avoid extra mechanical stresses and acceleration of chemical reaction in the encapsulating resin 214 even at high temperatures. In a dry environment, for example, at a low humidity environment to avoid invasion of moisture into the package, the structure disclosed herein can have a similar lifetime and reliability to ceramic and metal-can packages. Thus, according to the present embodiment, by use of the semiconductor device 100 it is possible to extend high temperature operation limits of the commercial off-the-shelf semiconductor devices to about above 150° C. for 200 to 400 hours.

According to the present embodiment, a semiconductor device 100 can be obtained with a short development term, low development cost, and low unit price. Further, such a semiconductor device 100 can be obtained without having the limitations imposed by the original commercially available packaging.

The semiconductor device of the present invention is applicable to high temperature applications, such as oilfield exploration and development in areas such as downhole fluid analysis using, for example, one or more fluid analysis modules in Schlumberger's Modular Formation Dynamics Tester (MDT). However, it is noted that uses of the semiconductor devices disclosed herein are not limited to the specific embodiments described herein. Rather, the present semiconductor devices have applicability to all situations that require high temperature durability and reliability such as, for example, in downhole oilfield applications. It is contemplated that the devices disclosed herein may be used in a variety of oilfield platforms, such as wireline, drilling and measuring, permanent monitoring, production logging, among other conventionally used oilfield technology.

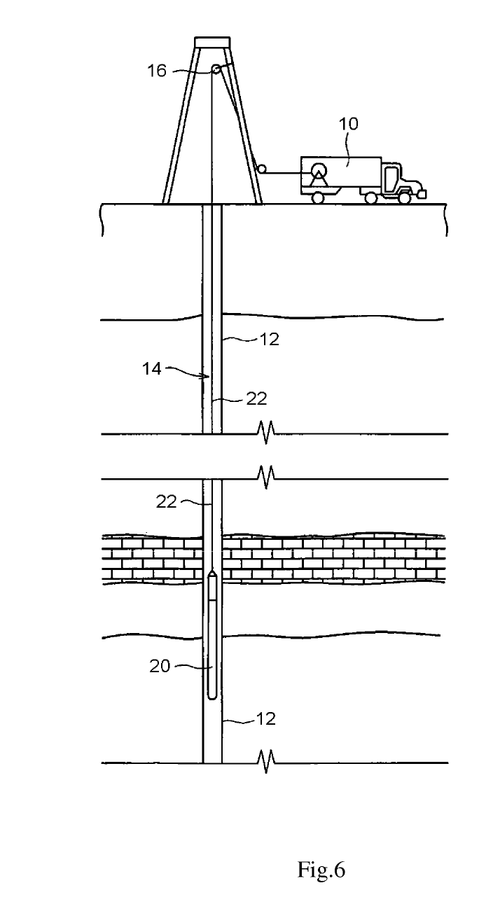

FIG. 6 is a schematic representation in cross-section of an exemplary operating environment for the present devices disclosed herein wherein a service vehicle 10 is situated at a wellsite having a borehole or wellbore 12 with a downhole tool 20 suspended therein at the end of a wireline 22. FIG. 6 depicts one possible setting for utilization of the present invention and other operating environments also are contemplated by the present invention. Typically, the borehole 12 contains a combination of fluids such as water, mud filtrate, formation fluids, etc. The downhole tool 20 and wireline 22 typically are structured and arranged with respect to the service vehicle 10 as shown schematically in FIG. 6, in an exemplary arrangement.

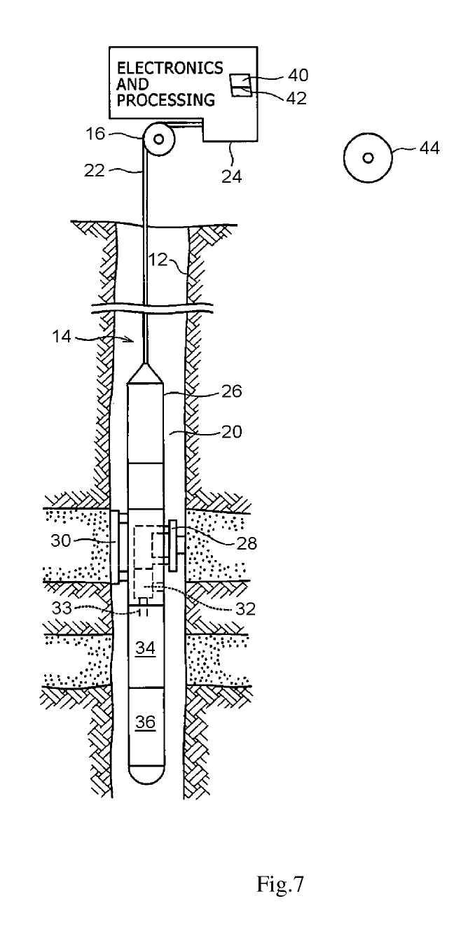

FIG. 7 is an exemplary embodiment of a system 14 for downhole analysis and sampling of formation fluids according to the present invention, for example, while the service vehicle 10 is situated at a wellsite (see FIG. 6). In FIG. 7, a borehole system 14 includes a downhole tool 20, which may be used for testing earth formations and analyzing the composition of fluids from a formation. The downhole tool 20 typically is suspended in the borehole 12 from the lower end of a multiconductor logging cable or wireline 22 spooled on a winch 16 at the formation surface. The logging cable 22 typically is electrically coupled to a surface electrical control system 24, included in the service vehicle 10 (see FIG. 6) for example, having appropriate electronics and processing systems for the downhole tool 20.

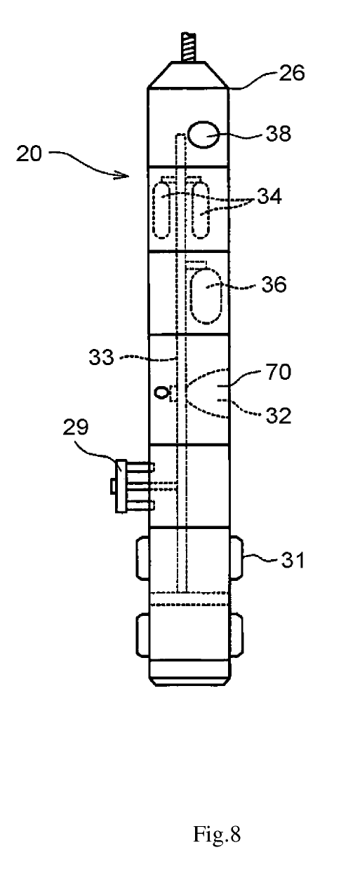

Referring also to FIG. 8, the downhole tool 20 includes an elongated tool body 26 encasing a variety of electronic components and modules, which are schematically represented in FIGS. 7 and 8, for providing necessary and desirable functionality to the downhole tool 20. The electronic components and modules housed in the tool body 26 may include one or more circuit boards having the semiconductor devices 100 as described above. Although the tool body 26 is suspended in the borehole 12 where the temperatures are very high, for example, about above 150° C., for long periods of time, the electronic modules and components perform properly since the semiconductor devices 100 included therein are structured and designed to extend the high temperature operational limits of the commercial off-the-shelf semiconductor devices.

A selectively extendible fluid admitting assembly 28 and a selectively extendible tool-anchoring member 30 are respectively arranged on opposite sides of the tool body 26. Fluid admitting assembly 28 is operable for selectively sealing off or isolating selected portions of a borehole wall 12 such that pressure or fluid communication with adjacent earth formation is established. The fluid admitting assembly 28 may be a single probe module 29 and/or a packer module 31. Examples of downhole tools are disclosed in U.S. Pat. Nos. 3,780,575, 3,859,851 and 4,860,581. One or more fluid analysis modules 32 are provided in the tool body 26. Fluids obtained from a formation and/or borehole flow through a flowline 33, via the fluid analysis module or modules 32, and then may be discharged through a port of a pumpout module 38. Alternatively, formation fluids in the flowline 33 may be directed to one or more fluid collecting chambers 34 and 36, such as 1, 2¾, or 6 gallon sample chambers and/or six 450 cc multi-sample modules, for receiving and retaining the fluids obtained from the formation for transportation to the surface. In the fluid analysis module 32, a pressure and volume control unit (PVCU) 70 having an array of sensors is arranged. The sensors and the related components and circuitry of the downhole fluid analysis modules may include one or more devices of the type disclosed herein. Alternative fluid analysis applications may also utilize the devices of the present disclosure, such as production logging fluid analysis, drilling and measuring fluid analysis, testing fluid analysis (downhole and surface), coiled tubing fluid analysis, permanent fluid analysis, among others. The devices of the present invention also may be utilized in drill collars and other downhole tool components. For example, the devices disclosed herein may be utilized for components relating to downhole telemetry, signal processing, digital and analog devices, among others.

The fluid admitting assemblies, one or more fluid analysis modules, the flow path and the collecting chambers, and other operational elements of the downhole tool 20, are controlled by electrical control systems, such as the surface electrical control system 24 (see FIG. 7). Preferably, the electrical control system 24, and other control systems situated in the tool body 26, for example, include processor capability for characterization of formation fluids in the tool 20.

The system 14 of the present invention, in its various embodiments, preferably includes a control processor 40 operatively connected with the downhole tool 20. The control processor 40 is depicted in FIG. 7 as an element of the electrical control system 24. Preferably, the methods of the present invention are embodied in a computer program that runs in the processor 40 located, for example, in the control system 24. In operation, the program is coupled to receive data, for example, from the fluid analysis module 32, via the wireline cable 22, and to transmit control signals to operative elements of the downhole tool 20.

The computer program may be stored on a computer usable storage medium 42 associated with the processor 40, or may be stored on an external computer usable storage medium 44 and electronically coupled to processor 40 for use as needed. The storage medium 44 may be any one or more of presently known storage media, such as a magnetic disk fitting into a disk drive, or an optically readable CD-ROM, or a readable device of any other kind, including a remote storage device coupled over a switched telecommunication link, or future storage media suitable for the purposes and objectives described herein.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A downhole tool, comprising:
a tool body; and
an electronic module housed in said tool body, which includes a circuit board having a semiconductor device, said semiconductor device including:
a die;
a bonding pad which is attached to the surface of said die;
a bonding wire which is attached to said bonding pad;
a bonding point which is formed on said bonding pad for connecting said bonding wire to said bonding pad;
an encapsulating resin partially encapsulating said die and being provided with a cavity such that a connecting portion of said bonding point and said bonding pad is exposed out of said resin in said cavity; and
a lid on said encapsulating resin to cover said cavity.

2. The downhole tool as claimed in claim 1, wherein said lid comprises a ceramic member, a metal member, a plastic member or a glass member.

3. The downhole tool as claimed in claim 1, wherein said lid is attached to said encapsulating resin via an adhesive composed of a thermosetting resin.

4. The downhole tool as claimed in claim 1, wherein said encapsulating resin is composed of a plastic including epoxy resin.

5. The downhole tool as claimed in claim 1, wherein said encapsulating resin is composed of a plastic including epoxy resin and a chemical material that functions as a flame retardant.

6. The downhole tool as claimed in claim 1, wherein said bonding pad is formed of aluminum.

7. The downhole tool as claimed in claim 1, wherein said bonding point connecting said bonding pad and said bonding wire is formed of gold.

8. A semiconductor device, comprising:
a die;
a bonding pad which is attached to the surface of said die;
a bonding wire which is attached to said bonding pad;
a bonding point which is formed on said bonding pad for connecting said bonding wire to said bonding pad;
an encapsulating resin partially encapsulating said die and being provided with a cavity such that a connecting portion of said bonding point and said bonding pad is exposed out of said resin in said cavity; and
a lid on said encapsulating resin to cover said cavity.

9. The semiconductor device as claimed in claim 8, wherein said lid comprises a ceramic member, a metal member, a plastic member or a glass member.

10. The semiconductor device as claimed in claim 8, wherein said lid is attached to said encapsulating resin via an adhesive composed of a thermosetting resin.

11. The semiconductor device as claimed in claim 8, wherein said encapsulating resin is composed of a plastic including epoxy resin.

12. The semiconductor device as claimed in claim 8, wherein said encapsulating resin is composed of a plastic including epoxy resin and a chemical material that functions as a flame retardant.

13. The semiconductor device as claimed in claim 8, wherein said bonding pad is formed of aluminum.

14. The semiconductor device as claimed in claim 8, wherein said bonding point connecting said bonding pad and said bonding wire is formed of gold.

15. A method of manufacturing a semiconductor device, comprising:
forming a cavity at a top side of a plastic encapsulant materials (PEM) semiconductor device,
wherein said semiconductor device including a die; a bonding pad which is attached to the surface of said die; a bonding wire which is attached to said bonding pad; a bonding point which is formed on said bonding pad for connecting said bonding wire to said bonding pad; and an encapsulating resin that fully encapsulates said die to embed said die therein,
said cavity being formed by removing a part of said encapsulating resin such that a connecting portion of said bonding point and said bonding pad is exposed out of said resin in said cavity; and
attaching a lid on said encapsulating resin to cover said cavity.

16. The method of manufacturing a semiconductor device as claimed in claim 15, wherein said lid is attached on said encapsulating resin via an adhesive.

17. The method of manufacturing a semiconductor device as claimed in claim 15, further comprising before forming the cavity, determining the area for forming said cavity based on the structure of said plastic encapsulant materials (PEM) semiconductor device.
